(19) United States
(12) Patent Application Publication
(10) Pub. No.: US 2026/0059855 A1
(43) Pub. Date: Feb. 26, 2026

(54) TERMINAL REGION CONTACT STRUCTURES FOR FIELD-EFFECT TRANSISTORS

(71) Applicant: International Business Machines Corporation, Armonk, NY (US)

(72) Inventors: Shay Reboh, Guilderland, NY (US); Oleg Gluschenkov, Tannersville, NY (US); Ruilong Xie, Niskayuna, NY (US); James P Mazza, Saratoga Springs, NY (US); Utkarsh Bajpai, Delmar, NY (US); Nicholas Anthony Lanzillo, Wynantskill, NY (US); Shahrukh Khan, Sandy Hook, CT (US)

(21) Appl. No.: 18/814,017

(22) Filed: Aug. 23, 2024

(51) Int. Cl. H01L 27/092; H01L 29/04; H01L 29/06; H01L 29/08; H01L 29/417; H01L 29/423; H01L 29/66; H01L 29/775; H01L 29/786

(52) U.S. Cl. CPC H10D 84/856; H10D 62/151; H10D 62/40; H10D 64/254; H10D 30/014; H10D 30/43; H10D 30/6735; H10D 30/6757; H10D 62/121

(57) ABSTRACT

A semiconductor device includes a transistor including a terminal region, wherein the terminal region includes doped semiconductor sidewall portions, a conductive layer disposed through the terminal region, wherein the doped semiconductor sidewall portions are disposed on sides of the conductive layer, and a via connected to the conductive layer.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments of the invention provide structures for and techniques for forming terminal region contact structures for FETs.

In one embodiment, a semiconductor device includes a transistor including a terminal region, wherein the terminal region includes doped semiconductor sidewall portions, a conductive layer disposed through the terminal region, wherein the doped semiconductor sidewall portions are disposed on sides of the conductive layer, and a via connected to the conductive layer.

In another embodiment, a semiconductor device includes a transistor including a conductive layer disposed through at least a source region, wherein the source region includes doped semiconductor portions disposed on sides of the conductive layer. A via is connected to the conductive layer and disposed in a dielectric layer under the transistor.

In another embodiment, a semiconductor device includes a first device level including a first nanosheet transistor, a second device level stacked on the first device level and including a second nanosheet transistor, and a conductive layer disposed in at least one of a source region and a drain region of the second nanosheet transistor. Doped semiconductor portions contact sides of the conductive layer in the at least one of the source region and the drain region.

These and other features and advantages of embodiments described herein will become more apparent from the accompanying drawings and the following detailed description.

### BRIEF DESCRIPTION OF THE DRAWINGS

FIG. 1A depicts a cross-sectional view of a semiconductor structure following formation of a via extending to a backside of the semiconductor structure, according to an embodiment of the invention.

FIG. 1B depicts a cross-sectional view of the semiconductor structure from FIG. 1A following formation of a middle dielectric layer, formation of a nanosheet transistor and deposition of a doped semiconductor layer for source and drain regions of the nanosheet transistor, according to an embodiment of the invention.

FIG. 1C depicts a cross-sectional view of the semiconductor structure from FIG. 1B following deposition of a first upper level dielectric layer on and between portions of the doped semiconductor layer, according to an embodiment of the invention.

FIG. 1D depicts a cross-sectional view of the semiconductor structure from FIG. 1C following removal of portions of the first upper level dielectric layer from on and between portions of the doped semiconductor layer, according to an embodiment of the invention.

FIG. 1E depicts a cross-sectional view of the semiconductor structure from FIG. 1D following recessing of portions of the doped semiconductor layer, according to an embodiment of the invention.

FIG. 1F depicts a cross-sectional view of the semiconductor structure from FIG. 1E following deposition of a second upper level dielectric layer, according to an embodiment of the invention.

FIG. 1G depicts a cross-sectional view of the semiconductor structure from FIG. 1F following removal of portions of the first and second upper level dielectric layers, of a portion of the doped semiconductor layer and of a portion of an underlying middle dielectric layer to form cavities for conductive layers, according to an embodiment of the invention.

FIG. 1H depicts a cross-sectional view of the semiconductor structure from FIG. 1G following formation of conductive layers, formation of a third upper level dielectric layer and of formation of frontside and backside interconnect layers, according to an embodiment of the invention.

FIG. 1I depicts an enlarged view of FIG. 1H showing grain boundaries in the doped semiconductor layer portions for source and drain regions of the nanosheet transistor, according to an embodiment of the invention.

FIG. 2A depicts a cross-sectional view of a semiconductor structure following formation of a via extending to a backside of the semiconductor structure, according to an embodiment of the invention.

FIG. 2B depicts a cross-sectional view of the semiconductor structure from FIG. 2A following formation of a middle dielectric layer, formation of a nanosheet transistor and growth of doped semiconductor portions for source and drain regions of the nanosheet transistor, according to an embodiment of the invention.

FIG. 2C depicts a cross-sectional view of the semiconductor structure from FIG. 2B following deposition of a first upper level dielectric layer on and between portions of the doped semiconductor portions, according to an embodiment of the invention.

FIG. 2D depicts a cross-sectional view of the semiconductor structure from FIG. 2C following removal of portions of the first upper level dielectric layer and of a portion of an underlying middle dielectric layer to form cavities for conductive layers, according to an embodiment of the invention.

FIG. 2E depicts a cross-sectional view of the semiconductor structure from FIG. 2D following formation of conductive layers, formation of a second upper level dielectric layer and formation of frontside and backside interconnect layers, according to an embodiment of the invention.

FIG. 3A depicts a cross-sectional view of a semiconductor structure following formation of a via extending to a backside of the semiconductor structure, according to an embodiment of the invention.

FIG. 3B depicts a cross-sectional view of the semiconductor structure from FIG. 3A following formation of a nanosheet transistor and growth of doped semiconductor portions for source and drain regions of the nanosheet transistor, according to an embodiment of the invention.

FIG. 3C depicts a cross-sectional view of the semiconductor structure from FIG. 3B following deposition of a first upper level dielectric layer on the doped semiconductor portions, according to an embodiment of the invention.

FIG. 3D depicts a cross-sectional view of the semiconductor structure from FIG. 3C following removal of portions of the first upper level dielectric layer, of portions of the doped semiconductor portions and of portions of an underlying middle dielectric layer to form cavities for conductive layers, according to an embodiment of the invention.

FIG. 3E depicts a cross-sectional view of the semiconductor structure from FIG. 3D following formation of conductive layers, formation of a second upper level dielectric layer and formation of frontside and backside interconnect layers, according to an embodiment of the invention.

FIG. 4 depicts a cross-sectional view of the semiconductor structure of FIG. 3E including a cross-section line A-A′, according to an embodiment of the invention.

FIG. 5 depicts a cross-sectional view of the semiconductor structure of FIG. 4 taken along the line A-A′, according to a first alternative embodiment of the invention.

FIG. 6 depicts a cross-sectional view of the semiconductor structure of FIG. 4 taken along the line A-A′, according to a second alternative embodiment of the invention.

### DETAILED DESCRIPTION

Illustrative embodiments of the invention may be described herein in the context of illustrative methods for forming terminal region contact structures for FETs, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having terminal regions including a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 3 to 20 nanometers (nm). Nanosheets and nanowires are viable options for scaling to 7 nm and beyond. A general process flow for formation of a nanosheet stack involves selectively removing sacrificial layers, which may be formed of silicon germanium (SiGe) between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to area reduction (e.g., such as 30-40% area reduction for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

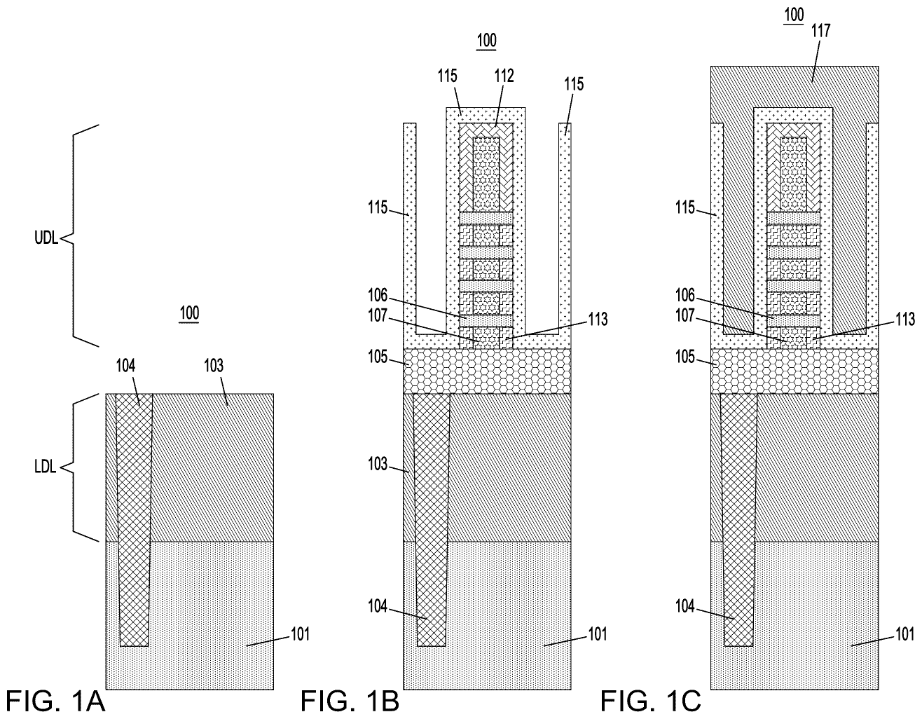

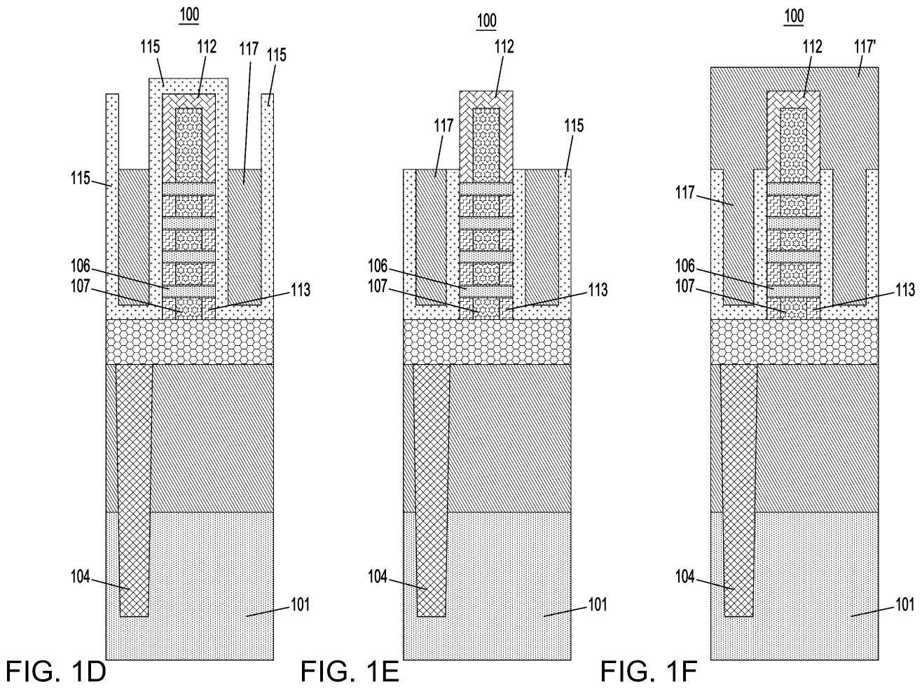

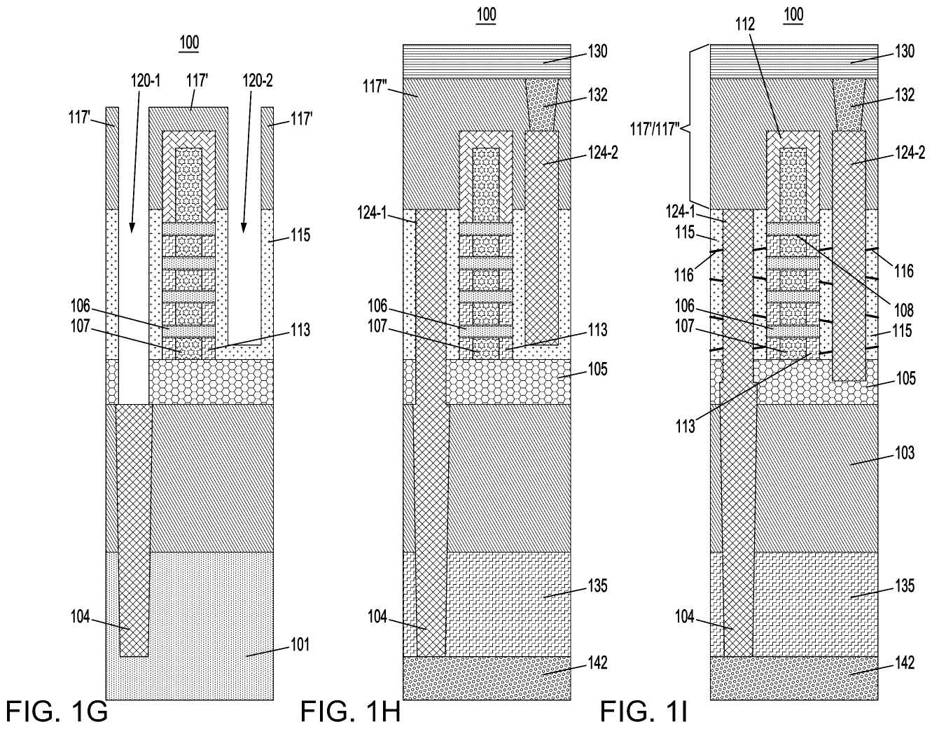

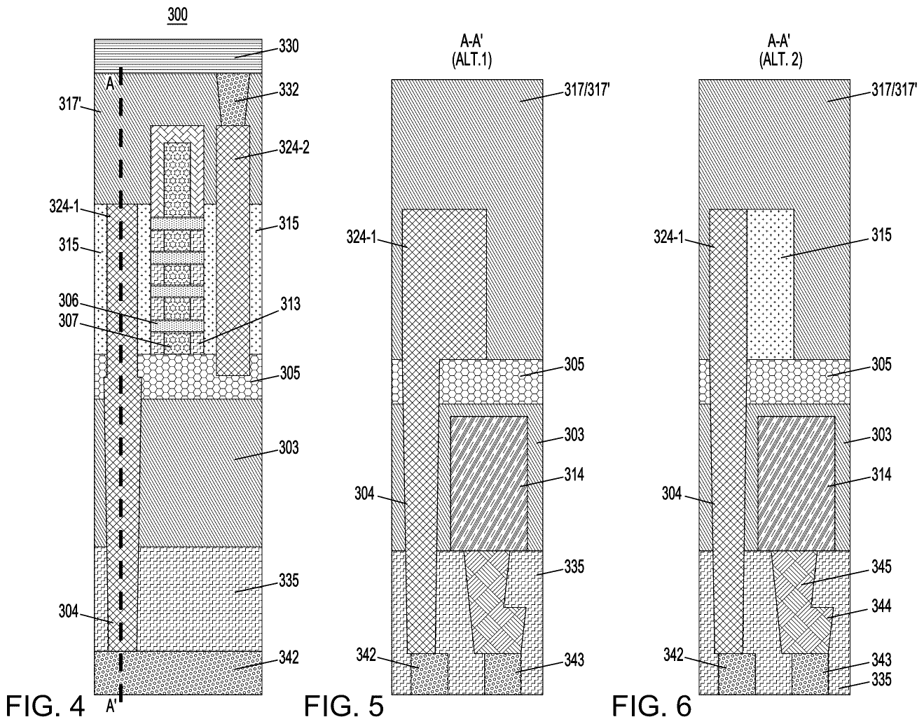

The cross-sectional views in FIGS. 1A-1I, 2A-2E, 3A-3E and 4 are taken across gate structures and the cross-sectional views in FIGS. 5 and 6 are taken along the line A-A′ in FIG. 4.

FIG. 1A depicts a cross-sectional view of a semiconductor structure 100 following formation of a via 104 extending to a backside of the semiconductor structure 100. A semiconductor substrate 101 includes semiconductor material including, but not limited to, silicon, III-V, II-V compound semiconductor materials or other like semiconductor materials. In addition, multiple layers of the semiconductor materials can be used as the semiconductor material of the semiconductor substrate 101. A lower device level (LDL) including one or more nanosheet transistors (not shown) is formed on the semiconductor substrate 101. The one or more nanosheet transistors are the same as or similar to the nanosheet transistor formed in the upper device level (UDL) and described in more detail in connection with FIGS. 1B-1I. As explained in more detail in connection with FIGS. 5 and 6, the positions of transistors in the lower device level are not aligned with and are staggered with respect to the transistors in the upper device level. For example, referring to the embodiment in FIGS. 1A-1I, nanosheet transistors in the lower device level are offset with respect to nanosheet transistors in the upper device level and not directly under the nanosheet transistors in the upper device level.

As used herein, “frontside or “first side” refers to a side on top of the semiconductor substrate 101 and/or in front of, on top of or in an upward direction from the lower device level and/or upper device level in the orientation shown in the cross-sectional figures. As used herein, “backside” or “second side” refers to a side below the semiconductor substrate 101 and/or behind, under, below or in a downward direction from the lower device level and/or upper device level in the orientation shown in the cross-sectional figures (e.g., opposite the “frontside”).

A lower level dielectric layer 103 is formed on the semiconductor substrate 101 and can be formed on and around nanosheet transistors of the lower device level. In illustrative embodiments, the lower level dielectric layer 103 may include, for example, silicon dioxide (SiO₂), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) or combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

A via 104 is formed through the lower level dielectric layer 103 and into the semiconductor substrate 101. In forming the via 104, an opening is formed through a portion of the lower level dielectric layer 103 and into the semiconductor substrate 101. According to an embodiment, masks are formed on parts of the lower level dielectric layer 103, and an exposed portion of the lower level dielectric layer 103 and underlying portion of the semiconductor substrate 101 corresponding to where the opening is to be formed are removed using, for example, a dry etching process using a reactive ion etch (RIE) or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers including, for example, a silicide layer, such as Ni, Ti, NiPt, etc., a metal adhesion layer, such as TiN, and a conductive metal fill layer, such as W, Al, Co, Ru, etc., are deposited in the opening and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the lower level dielectric layer 103. In some embodiments, the via 104 may include the conductive metal fill layer without one or more of the silicide layer and metal adhesion layer.

Referring to FIG. 1B, a middle dielectric layer 105, a nanosheet transistor and a doped semiconductor layer 115 for source and drain regions of the nanosheet transistor are formed on the lower device level. The middle dielectric layer 105 is deposited on the lower level dielectric layer 103 including the via 104 formed therein. In illustrative embodiments, the middle dielectric layer 105 includes the same material as or similar material to that of the lower level dielectric layer 103 and can be formed using the same techniques or similar techniques to those used to form the lower level dielectric layer 103.

The nanosheet transistor formed in the upper device level includes a plurality of channel layers 106 alternately stacked with and surrounded by gate structures 107. The embodiments are not necessarily limited to the shown number of channel layers 106, and there may be more or less layers in the same alternating configuration with the gate structures 107 depending on design constraints.

In the semiconductor structure 100, gate spacers 112 are disposed on sides and on top of an uppermost one of the gate structures 107. The spacer material can include for example, one or more dielectrics, including, but not necessarily limited to, SiN, SiON, SiOC, SiCN, BN, SiBN, SiBCN, SiOCN, SiOₓ, and combinations thereof. The gate spacers 112 can be formed by any suitable technique such as deposition followed by directional etching. Deposition may include, but is not limited to, ALD or CVD. Directional etching may include, but is not limited to, RIE.

Inner spacers 113 are disposed on sides of lower ones of the gate structures 107 above and/or under end portions of the channel layers 106. The material of the inner spacers 113 can include, but is not necessarily limited to, a nitride, such as, SiN, SiON, SiCN, BN, SiBN, SiBCN or SiOCN. In an illustrative embodiment, the gate spacers 112 are formed from the same or similar material to that of the inner spacers 113. Like the gate spacers 112, the inner spacers 113 can be formed by any suitable techniques such as deposition followed by isotropic etching.

The channel layers 106 include, for example, silicon or other semiconductor material. The gate structures 107, include, for example, gate portions (also referred to herein as “gate regions”) and dielectric portions. In illustrative embodiments, each gate structure 107 includes a gate dielectric layer 108 (see FIG. 1I) such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate portion of each gate structure 107 includes a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer 108. It should be appreciated that various other materials may be used for the metal gate portions as desired.

A doped semiconductor layer 115 is conformally deposited on upper surfaces of the middle dielectric layer 105 and on side portions and upper surfaces of the nanosheet transistor structure including side portions of the channel layers 106, gate spacers 112 and inner spacers 113, and upper surfaces of the gate spacers 112. The conformal deposition process includes, for example, ALD or CVD. It is to be understood that there are additional nanosheet transistors (not shown) in the upper device layer, which are adjacent the shown nanosheet transistor, and on which the outer vertical portions of the doped semiconductor layer 115 are formed. The material of the doped semiconductor layer 115 includes, for example, doped amorphous semiconductor material (e.g., doped amorphous silicon). In illustrative embodiments, the doped semiconductor layer 115 is doped with, for example, in the case of n-type FETS (nFETs), n-type dopants including, for example, phosphorus (P), arsenic (As) and antimony (Sb), and in the case of p-type FETS (pFETs), with n-type dopants including, for example, boron (B), boron fluoride (BF₂), gallium (Ga), indium (In), and thallium (Tl).

Referring to FIG. 1C, a first upper level dielectric layer 117 is deposited on and between portions of the doped semiconductor layer 115. In an illustrative embodiment, the first upper level dielectric layer 117 includes the same material as or similar material to that of the lower level dielectric layer 103 and can be formed using the same techniques or similar techniques to those used to form the lower level dielectric layer 103. Referring to FIG. 1D, portions of the first upper level dielectric layer 117 are selectively removed from on and between portions of the doped semiconductor layer 115 so that the remaining portions of the first upper level dielectric layer 117 are recessed with respect to upper portions of the doped semiconductor layer 115. The selective removal of the portions of the first upper level dielectric layer 117 can be performed using, for example, a RIE process.

Referring to FIG. 1E, portions of the doped semiconductor layer 115 not covered by the first upper level dielectric layer 117 are removed using, for example, an ammonia-based wet etch process or a RIE process. Then, referring to FIG. 1F, a second upper level dielectric layer 117′ is deposited on the structure from FIG. 1E. In an illustrative embodiment, the second upper level dielectric layer 117′ includes the same material as or similar material to that of the first upper level dielectric layer 117 and can be formed using the same techniques or similar techniques to those used to form the first upper level dielectric layer 117.

Referring to FIG. 1G, portions of the second upper level dielectric layer 117′ and remaining portions of the first upper level dielectric layer 117 exposed following the removal of the portions of the second upper level dielectric layer 117′ are removed using, for example, a RIE process. Then, an exposed bottom portion of the doped semiconductor layer 115 is removed on the left side of the nanosheet transistor in FIG. 1G to expose a portion of the middle dielectric layer 105, which is also removed to expose a top surface of the via 104. The removal of the exposed bottom portion of the doped semiconductor layer 115 is performed using, for example, a RIE process, and the removal of the underlying portion of the middle dielectric layer 105 is performed using, for example, a RIE process. As can be seen in FIGS. 1G and 1H, the removal processes result in a first cavity 120-1 and a second cavity 120-2 where first and second conductive layers 124-1 and 124-2 are respectively formed.

Referring to FIG. 1H, the first conductive layer 124-1 is formed by depositing conductive material in the first cavity 120-1 and the second conductive layer 124-2 is formed by depositing conductive material in the second cavity 120-2. The first conductive layer 124-1 extends through the middle dielectric layer 105 to contact the top surface of the via 104. The second conductive layer 124-2 contacts a bottom portion of the doped semiconductor layer 115 on a right side of the nanosheet transistor in FIG. 1H. In illustrative embodiments, the doped semiconductor layer 115 on the right side of the nanosheet transistor functions as a drain of the nanosheet transistor and the doped semiconductor layer 115 on the left side of the nanosheet transistor functions as a source of the nanosheet transistor.

The portions of the doped semiconductor layer 115 forming the source and drain of the nanosheet transistor may be referred to herein as “doped semiconductor sidewall portions” or “doped semiconductor portions.” The first and second conductive layers 124-1 and 124-2 are disposed through the respective terminal regions (e.g., source and drain regions), wherein the portions of the doped semiconductor layer 115 (e.g., doped semiconductor sidewall portions) are disposed on sides of the first and second conductive layers 124-1 and 124-2. Similar to the via 104, the first and second conductive layers 124-1 and 124-2 include metal layers including, for example, a silicide layer, such as Ni, Ti, NiPt, etc., a metal adhesion layer, such as TiN, and a conductive metal fill layer, such as W, Al, Co, Ru, etc. In some embodiments, the first and second conductive layers 124-1 and 124-2 may include the conductive metal fill layer without one or more of the silicide layer and metal adhesion layer. In illustrative embodiments, the first and second conductive layers 124-1 and 124-2 include different materials from that of the via 104.

A third upper level dielectric layer 117″, which is the same as or similar to the first and second upper level dielectric layers 117 and 117′ fills in areas on and around the first and second conductive layers 124-1 and 124-2, the upper portion of the nanosheet transistor and on top surfaces of the portions of the doped semiconductor layer 115 forming the source and drain of the nanosheet transistor. As can be understood from FIG. 1H, the first conductive layer 124-1 is connected to a backside contact 142 through the via 104. In illustrative embodiments, the backside contact includes a backside power rail connected to a backside power delivery network (BSPDN). It is to be understood that, in illustrative embodiments, the backside contact 142 can be connected to a voltage source (e.g., source voltage (VSS), drain voltage (VDD)), an input signal portion or an output signal portion depending on circuit design. The second conductive layer 124-2 is connected to a frontside interconnect portion 130 through a frontside contact 132. In more detail, the frontside interconnect portion 130 includes frontside back-end-of-line (BEOL) interconnects formed on the combination of the second and third upper level dielectric layers 117′ and 117″. The frontside contact 132 extends through a portion of the combination of the second and third upper level dielectric layers 117′ and 117″ between the frontside interconnect portion 130 and the second conductive layer 124-2 to connect the second conductive layer 124-2 to the frontside interconnect portion 130. The frontside contact 132 includes conductive materials the same as or similar to the materials of the first and second conductive layers 124-1 and 124-2. The frontside interconnect portion 130 (e.g., frontside BEOL interconnects) includes various BEOL interconnect structures which may electrically connect to the frontside contact 132. It is to be understood that, in illustrative embodiments, the frontside interconnect portion 130 can be connected to a voltage source (e.g., VSS, VDD), an input signal portion or an output signal portion depending on circuit design.

Using a carrier wafer (not shown), the semiconductor structure 100 may be “flipped” (e.g., rotated 180 degrees) so that the structure is inverted. Following flipping, the semiconductor substrate 101 is removed from the backside of the semiconductor structure 100, and replaced with backside dielectric layer 135. In an illustrative embodiment, the backside dielectric layer 135 includes the same material as or similar material to that of the first, second and third upper level dielectric layers 117, 117′ and 117″ and can be formed using the same techniques or similar techniques to those used to form the first, second and third upper level dielectric layers 117, 117′ and 117″. As can be seen, the backside dielectric layer 135 is formed around the via 104. A backside contact 142 is formed through a portion of the backside dielectric layer 135. Like the frontside contact 132, the backside contact 142 includes conductive materials the same as or similar to the materials of the first and second conductive layers 124-1 and 124-2. A BSPDN (not shown) (also referred to herein as backside interconnects) is formed on the backside dielectric layer 135 to connect to the backside contact 142. The BSPDN includes various BSPDN structures such as, but not necessarily limited to, interconnects in a power supply path from voltage regulator modules (VRMs) to circuits. The interconnects can include, for example, power and ground planes in circuit boards, cables, connectors and capacitors associated with a power supply. Backside power delivery prevents BEOL routing congestion, resulting in power performance benefits. The BSPDN delivers a source voltage to the portion of the doped semiconductor layer 115 forming the source of the nanosheet transistor on the left side of the nanosheet transistor in FIG. 1H. The source voltage is delivered through the backside contact 142, the via 104 and the first conductive layer 124-1. The frontside interconnect portion 130 provides a drain voltage to the portion of the doped semiconductor layer 115 forming the drain of the nanosheet transistor on the right side of the nanosheet transistor in FIG. 1H. The drain voltage is delivered through the frontside contact 132 and the second conductive layer 124-2.

Referring to FIG. 1I, which is an enlarged view of FIG. 1H, the portions of the doped semiconductor layer 115 forming the source and drain of the nanosheet transistor (e.g., doped semiconductor sidewall portions) include a plurality of different crystal grains. Grain boundaries 116 between the crystal grains are formed as a result of recrystallization of the amorphous semiconductor material following the conformal deposition of the amorphous semiconductor material. Grain boundaries 116 of at least a portion of a plurality of different crystal grains are disposed between at least two adjacent channel layers 106 of the plurality of channel layers 106.

As noted hereinabove, the nanosheet transistor in the upper device layer is staggered with respect to a nanosheet transistor disposed in the lower device layer. At least a portion of the via 104 is disposed in the backside dielectric layer 135 on a side of the nanosheet transistor disposed in the lower device layer.

As can be understood, the portions of the doped semiconductor layer 115 forming the source and drain of the nanosheet transistor (e.g., doped semiconductor sidewall portions) each include a first continuous layer disposed on a first side of the corresponding first or second conductive layer 124-1 or 124-2 and a second continuous layer disposed on a second side of the corresponding first or second conductive layer 124-1 or 124-2.

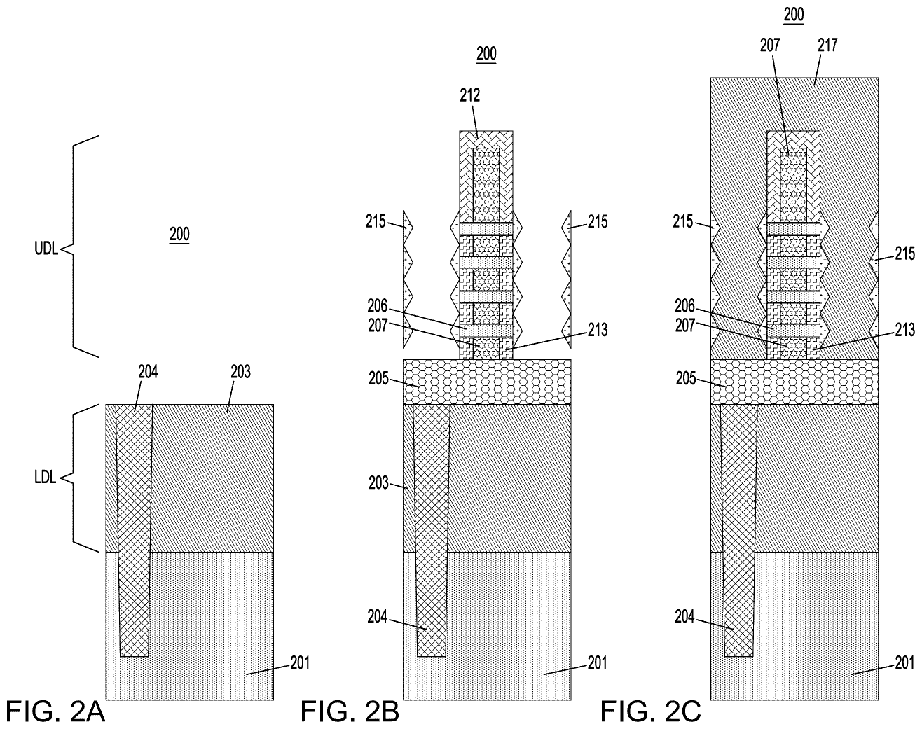

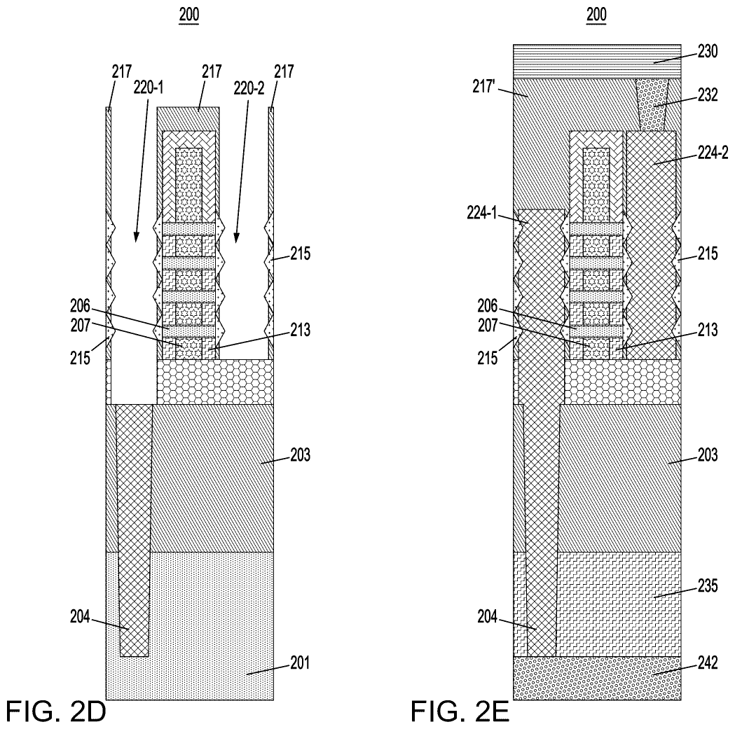

Referring to FIGS. 2A-2E, another semiconductor structure 200 is shown and described. The same or similar reference numbers are used in FIGS. 2A-2E to denote the same or similar features, elements, or structures as in FIGS. 1A-1I, and thus, a detailed explanation of the same or similar features, elements, or structures is not repeated for FIGS. 2A-2E.

Referring to FIG. 2A, similar to FIG. 1A, a cross-sectional view of a semiconductor structure 200 is depicted. FIG. 2A illustrates the semiconductor structure 200 following formation of a via 204 extending to a backside of the semiconductor structure 200. A lower device level (LDL) including one or more nanosheet transistors (not shown) is formed on a semiconductor substrate 201. The one or more nanosheet transistors are the same as or similar to the nanosheet transistor formed in the upper device level (UDL) and described in more detail in connection with FIGS. 2B-2E. As noted herein, the positions of transistors in the lower device level are not aligned with and are staggered with respect to the transistors in the upper device level.

A lower level dielectric layer 203 is formed on the semiconductor substrate 201 and can be formed on and around nanosheet transistors of the lower device level. In illustrative embodiments, the lower level dielectric layer 203 may include, for example, the same materials as or similar materials to the lower level dielectric layer 103, and is deposited using the same deposition techniques as or similar deposition techniques to those used for the lower level dielectric layer 103. A via 204, which is the same as or similar to the via 104, is formed through the lower level dielectric layer 203 and extends into the semiconductor substrate 201.

Referring to FIG. 2B, a middle dielectric layer 205, a nanosheet transistor and doped semiconductor portions 215 for source and drain regions of the nanosheet transistor are formed on the lower device level of the semiconductor structure 200. The middle dielectric layer 205 is the same as or similar to the middle dielectric layer 105, and is deposited on the lower level dielectric layer 203 including the via 204 formed therein.

Similar to the nanosheet transistor described in connection with the semiconductor structure 100, the nanosheet transistor formed in the upper device level of the semiconductor structure 200 includes a plurality of channel layers 206 alternately stacked with and surrounded by gate structures 207. The embodiments are not necessarily limited to the shown number of channel layers 206, and there may be more or less layers in the same alternating configuration with the gate structures 207 depending on design constraints.

In the semiconductor structure 200, like the gate spacers 112, gate spacers 212 are disposed on sides and on top of an uppermost one of the gate structures 207. Like the inner spacers 113 of the semiconductor structure 100, inner spacers 213 are disposed on sides of lower ones of the gate structures 207 above and/or under end portions of the channel layers 206. The materials and configuration of the channel layers 206, gate structures 207, gate spacers 212 and inner spacers 213 of the semiconductor structure 200 are the same as or similar to the materials and configuration of the channel layers 106, gate structures 107, gate spacers 112 and inner spacers 113 of the semiconductor structure 100.

Doped semiconductor portions 215 are epitaxially grown from exposed ends of the channel layers 206 in an epitaxial growth process. It is to be understood that there are additional nanosheet transistors (not shown) in the upper device layer of the semiconductor structure 200, which are adjacent the shown nanosheet transistor, and from which the outer doped semiconductor portions 215 are epitaxially grown. As can be seen, the time of the epitaxial growth process is controlled so that the size of the doped semiconductor portions 215 is limited to leave space between adjacent doped semiconductor portions 215 in the horizontal (left-right) direction, which, as described herein, is filled by corresponding first and second conductive layers 224-1 and 224-2 (see FIG. 2E). Adjacent doped semiconductor portions 215 in the vertical (up-down) direction contact each other. As can be seen, the doped semiconductor portions 215 each have a pyramid and/or triangular shape.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

The material of the doped semiconductor portions 215 includes, for example, doped semiconductor material (e.g., doped silicon). In illustrative embodiments, the doped semiconductor portions 215 are doped with, for example, in the case of n-type FETS (nFETs), n-type dopants including, for example, phosphorus (P), arsenic (As) and antimony (Sb), and in the case of p-type FETS (pFETs), with n-type dopants including, for example, boron (B), boron fluoride (BF₂), gallium (Ga), indium (In), and thallium (Tl).

Referring to FIG. 2C, a first upper level dielectric layer 217 is deposited on and between the doped semiconductor portions 215, and on and around the nanosheet transistor including the gate spacers 212. In an illustrative embodiment, the first upper level dielectric layer 217 includes the same material as or similar material to that of the lower level dielectric layer 203 and can be formed using the same techniques or similar techniques to those used to form the lower level dielectric layer 203.

Referring to FIG. 2D, portions of the first upper level dielectric layer 217 are removed using, for example, a RIE process. Then, an exposed portion of the middle dielectric layer 205 on the left side of the nanosheet transistor in FIG. 2D is also removed to expose a top surface of the via 204. The removal of the portion of the middle dielectric layer 205 is performed using, for example, a RIE process. As can be seen in FIGS. 2D and 2E, the removal processes result in a first cavity 220-1 and a second cavity 220-2 where first and second conductive layers 224-1 and 224-2 are respectively formed.

Referring to FIG. 2E, the first conductive layer 224-1 is formed by depositing conductive material in the first cavity 220-1 and the second conductive layer 224-2 is formed by depositing conductive material in the second cavity 220-2. The first conductive layer 224-1 extends through the middle dielectric layer 205 to contact the top surface of the via 204. The second conductive layer 224-2 contacts a top surface of the middle dielectric layer 205 on a right side of the nanosheet transistor in FIG. 2E. In illustrative embodiments, the doped semiconductor portions 215 on the right side of the nanosheet transistor function as a drain of the nanosheet transistor and the doped semiconductor portions 215 on the left side of the nanosheet transistor function as a source of the nanosheet transistor.

The doped semiconductor portions 215 forming the source and drain of the nanosheet transistor may be referred to herein as “doped semiconductor sidewall portions.” The first and second conductive layers 224-1 and 224-2 are disposed through the respective terminal regions (e.g., source and drain regions), wherein the doped semiconductor portions 215 are disposed on sides of the first and second conductive layers 224-1 and 224-2. Similar to the via 204, the first and second conductive layers 224-1 and 224-2 include metal layers including, for example, a silicide layer, such as Ni, Ti, NiPt, etc., a metal adhesion layer, such as TiN, and a conductive metal fill layer, such as W, Al, Co, Ru, etc. In some embodiments, the first and second conductive layers 224-1 and 224-2 may include the conductive metal fill layer without one or more of the silicide layer and metal adhesion layer. In illustrative embodiments, the first and second conductive layers 224-1 and 224-2 include different materials from that of the via 204.

A second upper level dielectric layer 217′, which is the same as or similar to the first upper level dielectric layer 217 fills in areas on and around the first and second conductive layers 224-1 and 224-2, the upper portion of the nanosheet transistor and on top of the doped semiconductor portions 215 forming the source and drain of the nanosheet transistor. As can be understood from FIG. 2E, the first conductive layer 224-1 is connected to a backside contact 242 through the via 204. In illustrative embodiments, the backside contact includes a backside power rail connected to a BSPDN. It is to be understood that, in illustrative embodiments, the backside contact 242 can be connected to a voltage source (e.g., VSS, VDD), an input signal portion or an output signal portion depending on circuit design. The second conductive layer 224-2 is connected to a frontside interconnect portion 230 through a frontside contact 232. In more detail, the frontside interconnect portion 230 includes frontside BEOL interconnects formed on the combination of the first and second upper level dielectric layers 217 and 217′. The frontside contact 232 extends through a portion of the combination of the first and second upper level dielectric layers 217 and 217′ between the frontside interconnect portion 230 and the second conductive layer 224-2 to connect the second conductive layer 224-2 to the frontside interconnect portion 230. The frontside contact 232 includes conductive materials the same as or similar to the materials of the first and second conductive layers 224-1 and 224-2. The frontside interconnect portion 230 (e.g., frontside BEOL interconnects) includes various BEOL interconnect structures which may electrically connect to the frontside contact 232. It is to be understood that, in illustrative embodiments, the frontside interconnect portion 230 can be connected to a voltage source (e.g., VSS, VDD), an input signal portion or an output signal portion depending on circuit design.

Using a carrier wafer (not shown), the semiconductor structure 200 may be “flipped” (e.g., rotated 180 degrees) so that the structure is inverted. Following flipping, the semiconductor substrate 201 is removed from the backside of the semiconductor structure 200, and replaced with backside dielectric layer 235. In an illustrative embodiment, the backside dielectric layer 235 includes the same material as or similar material to that of the first and second upper level dielectric layers 217 and 217′, and can be formed using the same techniques or similar techniques to those used to form the first and second upper level dielectric layers 217 and 217′. As can be seen, the backside dielectric layer 235 is formed around the via 204. A backside contact 242 is formed through a portion of the backside dielectric layer 235. Like the frontside contact 232, the backside contact 242 includes conductive materials the same as or similar to the materials of the first and second conductive layers 224-1 and 224-2. A BSPDN (not shown) (also referred to herein as backside interconnects) is formed on the backside dielectric layer 235 to connect to the backside contact 242. The BSPDN includes various BSPDN structures such as, but not necessarily limited to, interconnects in a power supply path from voltage regulator modules (VRMs) to circuits. The interconnects can include, for example, power and ground planes in circuit boards, cables, connectors and capacitors associated with a power supply. Backside power delivery prevents BEOL routing congestion, resulting in power performance benefits. The BSPDN delivers a source voltage to the doped semiconductor portions 215 forming the source of the nanosheet transistor on the left side of the nanosheet transistor in FIG. 2E. The source voltage is delivered through the backside contact 242, the via 204 and the first conductive layer 224-1. The frontside interconnect portion 230 provides a drain voltage to the doped semiconductor portions 215 forming the drain of the nanosheet transistor on the right side of the nanosheet transistor in FIG. 2E. The drain voltage is delivered through the frontside contact 232 and the second conductive layer 224-2.

Like the semiconductor structure 100, in the semiconductor structure 200, the nanosheet transistor in the upper device layer is staggered with respect to a nanosheet transistor disposed in the lower device layer. At least a portion of the via 204 is disposed in the backside dielectric layer 235 on a side of the nanosheet transistor disposed in the lower device layer.

As can be understood, the doped semiconductor portions 215 include a plurality of first pyramid and/or triangular shaped portions disposed on a first side of a corresponding first or second conductive layer 224-1 or 224-2 and a plurality of second pyramid and/or triangular shaped portions disposed on a second side of a corresponding first or second conductive layer 224-1 or 224-2. Adjacent ones of the plurality of first pyramid and/or triangular shaped portions contact each other, and adjacent ones of the plurality of second pyramid and/or triangular shaped portions contact each other.

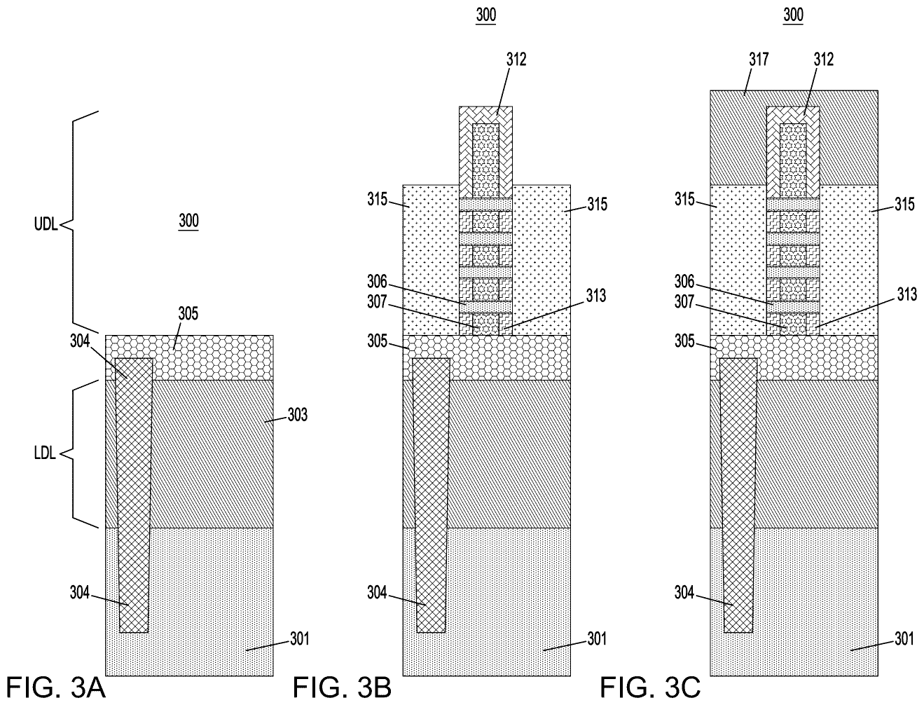

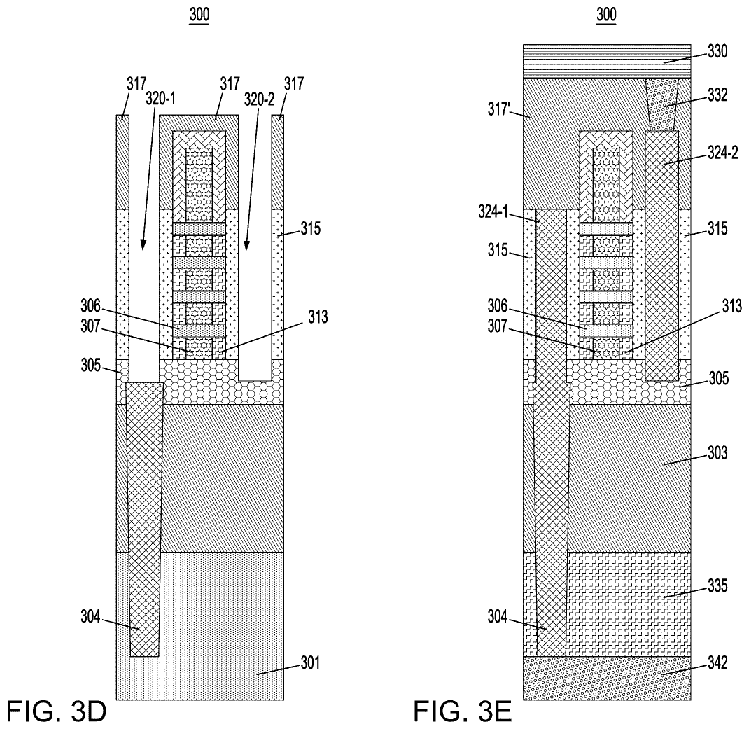

Referring to FIGS. 3A-3E, another semiconductor structure 300 is shown and described. The same or similar reference numbers are used in FIGS. 3A-3E to denote the same or similar features, elements, or structures as in FIGS. 1A-1I and FIGS. 2A-2E, and thus, a detailed explanation of the same or similar features, elements, or structures is not repeated for FIGS. 3A-3E.

Referring to FIG. 3A, similar to FIGS. 1A and 2A, a cross-sectional view of a semiconductor structure 300 is depicted. FIG. 3A illustrates the semiconductor structure 300 following formation of a via 304 extending to a backside of the semiconductor structure 300. A lower device level (LDL) including one or more nanosheet transistors (not shown) is formed on a semiconductor substrate 301. The one or more nanosheet transistors are the same as or similar to the nanosheet transistor formed in the upper device level (UDL) and described in more detail in connection with FIGS. 3B-3E. As noted herein, the positions of transistors in the lower device level are not aligned with and are staggered with respect to the transistors in the upper device level.

A lower level dielectric layer 303 is formed on the semiconductor substrate 301 and can be formed on and around nanosheet transistors of the lower device level. In illustrative embodiments, the lower level dielectric layer 303 may include, for example, the same materials as or similar materials to the lower level dielectric layer 103 or lower level dielectric layer 203, and is deposited using the same deposition techniques as or similar deposition techniques to those used for the lower level dielectric layer 103 or lower level dielectric layer 203. A middle dielectric layer 305 is formed on the lower level dielectric layer 303. The middle dielectric layer 305 is the same as or similar to the middle dielectric layer 105 or middle dielectric layer 205. A via 304, which is the same as or similar to the via 104 or via 204, is formed through the lower level dielectric layer 303 and extends into the semiconductor substrate 301. Different from the vias 104 and 204, an upper portion of the via 304 extends into the middle dielectric layer 305 through a bottom surface of the middle dielectric layer 305. The via 304 is recessed with respect to the middle dielectric layer 305, such that the upper portion of the middle dielectric layer 305 is entirely within and covered by the middle dielectric layer 305.

In an illustrative embodiment, this structure for the via 304 can be formed by depositing portions of the middle dielectric layer 305 in multiple steps. For example, a lower portion of the middle dielectric layer 305 is deposited on the lower level dielectric layer 303, and then an opening is formed through the lower portion of the middle dielectric layer 305, through the lower level dielectric layer 303 and into a portion of the semiconductor substrate 301. The opening is filled with the conductive material to form the via 304, and planarization (e.g., CMP) is performed to planarize an upper surface of the lower portion of the middle dielectric layer 305. Then, an upper portion of the middle dielectric layer 305 is deposited on the planarized surface to result in the semiconductor structure 300 in FIG. 3A, where the via 304 is recessed within the middle dielectric layer 305.

Referring to FIG. 3B, a nanosheet transistor and doped semiconductor layers 315 for source and drain regions of the nanosheet transistor are formed on the middle dielectric layer 305. Similar to the nanosheet transistor described in connection with the semiconductor structure 100 or 200, the nanosheet transistor formed in the upper device level of the semiconductor structure 300 includes a plurality of channel layers 306 alternately stacked with and surrounded by gate structures 307. The embodiments are not necessarily limited to the shown number of channel layers 306, and there may be more or less layers in the same alternating configuration with the gate structures 307 depending on design constraints.

In the semiconductor structure 300, like the gate spacers 112 or 212, gate spacers 312 are disposed on sides and on top of an uppermost one of the gate structures 307. Like the inner spacers 113 of the semiconductor structure 100 or the inner spacers 213 of the semiconductor structure 200, inner spacers 313 are disposed on sides of lower ones of the gate structures 307 above and/or under end portions of the channel layers 306. The materials and configuration of the channel layers 306, gate structures 307, gate spacers 312 and inner spacers 313 of the semiconductor structure 300 are the same as or similar to the materials and configuration of the channel layers 106/206, gate structures 107/207, gate spacers 112/212 and inner spacers 113/213 of the semiconductor structures 100/200.

Doped semiconductor layers 315 are epitaxially grown from exposed ends of the channel layers 306 in an epitaxial growth process. It is to be understood that there can be additional nanosheet transistors (not shown) in the upper device layer of the semiconductor structure 300, which are adjacent the shown nanosheet transistor, and from which the doped semiconductor layers 315 are also epitaxially grown.

The material of the doped semiconductor layers 315 includes, for example, doped semiconductor material (e.g., doped silicon). In illustrative embodiments, the doped semiconductor layers 315 are doped with, for example, in the case of n-type FETS (nFETs), n-type dopants including, for example, phosphorus (P), arsenic (As) and antimony (Sb), and in the case of p-type FETS (pFETs), with n-type dopants including, for example, boron (B), boron fluoride (BF₂), gallium (Ga), indium (In), and thallium (Tl).

Referring to FIG. 3C, a first upper level dielectric layer 317 is deposited on the doped semiconductor layers 315, and on and around the nanosheet transistor including the gate spacers 312. In an illustrative embodiment, the first upper level dielectric layer 317 includes the same material as or similar material to that of the lower level dielectric layer 303 and can be formed using the same techniques or similar techniques to those used to form the lower level dielectric layer 303.

Referring to FIG. 3D, portions of the first upper level dielectric layer 317 are removed using, for example, a RIE process. Then, underlying portions of the doped semiconductor layers 315 exposed by the removal of the portions of the first upper level dielectric layer 317 are removed using, for example, a RIE process. Underlying portions of the middle dielectric layer 305 exposed by the removal of the portions of the doped semiconductor layers 315 are removed using, for example, a RIE process. The removed portion of the middle dielectric layer 305 on the left side of the nanosheet transistor in FIG. 3D exposes a top surface of the via 304. As can be seen in FIGS. 3D and 3E, the removal processes result in a first cavity 320-1 and a second cavity 320-2 where first and second conductive layers 324-1 and 324-2 are respectively formed.

Referring to FIG. 3E, the first conductive layer 324-1 is formed by depositing conductive material in the first cavity 320-1 and the second conductive layer 324-2 is formed by depositing conductive material in the second cavity 320-2. The first conductive layer 324-1 extends through part of the middle dielectric layer 305 to contact the top surface of the via 304, which is in a lower part of the middle dielectric layer 305. The second conductive layer 324-2 penetrates a top surface of the middle dielectric layer 305 and includes a lower portion within the middle dielectric layer 305 on a right side of the nanosheet transistor in FIG. 3E. In illustrative embodiments, the remaining portions of the doped semiconductor layer 315 on the right side of the nanosheet transistor function as a drain of the nanosheet transistor and the remaining portions of the doped semiconductor layer 315 on the left side of the nanosheet transistor function as a source of the nanosheet transistor.

The portions of the doped semiconductor layers 315 forming the source and drain of the nanosheet transistor may be referred to herein as “doped semiconductor sidewall portions” or “doped semiconductor portions.” The first and second conductive layers 324-1 and 324-2 are disposed through the respective terminal regions (e.g., source and drain regions), wherein the portions of the doped semiconductor layers 315 (e.g., doped semiconductor sidewall portions) are disposed on sides of the first and second conductive layers 324-1 and 324-2. Similar to the via 304, the first and second conductive layers 324-1 and 324-2 include metal layers including, for example, a silicide layer, such as Ni, Ti, NiPt, etc., a metal adhesion layer, such as TiN, and a conductive metal fill layer, such as W, Al, Co, Ru, etc. In some embodiments, the first and second conductive layers 324-1 and 324-2 may include the conductive metal fill layer without one or more of the silicide layer and metal adhesion layer. In illustrative embodiments, the first and second conductive layers 324-1 and 324-2 include different materials from that of the via 304.

A second upper level dielectric layer 317′, which is the same as or similar to the first upper level dielectric layer 317 fills in areas on and around the first and second conductive layers 324-1 and 324-2, the upper portion of the nanosheet transistor and on top of and around the portions of the doped semiconductor layers 315 forming the source and drain of the nanosheet transistor. As can be understood from FIG. 3E, the first conductive layer 324-1 is connected to a backside contact 342 through the via 304. In illustrative embodiments, the backside contact includes a backside power rail connected to a BSPDN. It is to be understood that, in illustrative embodiments, the backside contact 342 can be connected to a voltage source (e.g., VSS, VDD), an input signal portion or an output signal portion depending on circuit design. The second conductive layer 324-2 is connected to a frontside interconnect portion 330 through a frontside contact 332. In more detail, the frontside interconnect portion 330 includes frontside BEOL interconnects formed on the combination of the first and second upper level dielectric layers 317 and 317′. The frontside contact 332 extends through a portion of the combination of the first and second upper level dielectric layers 317 and 317′ between the frontside interconnect portion 330 and the second conductive layer 324-2 to connect the second conductive layer 324-2 to the frontside interconnect portion 330. The frontside contact 332 includes conductive materials the same as or similar to the materials of the first and second conductive layers 324-1 and 324-2. The frontside interconnect portion 330 (e.g., frontside BEOL interconnects) includes various BEOL interconnect structures which may electrically connect to the frontside contact 332. It is to be understood that, in illustrative embodiments, the frontside interconnect portion 330 can be connected to a voltage source (e.g., VSS, VDD), an input signal portion or an output signal portion depending on circuit design.

Using a carrier wafer (not shown), the semiconductor structure 300 may be “flipped” (e.g., rotated 180 degrees) so that the structure is inverted. Following flipping, the semiconductor substrate 301 is removed from the backside of the semiconductor structure 300, and replaced with backside dielectric layer 335. In an illustrative embodiment, the backside dielectric layer 335 includes the same material as or similar material to that of the first and second upper level dielectric layers 317 and 317′, and can be formed using the same techniques or similar techniques to those used to form the first and second upper level dielectric layers 317 and 317′. As can be seen, the backside dielectric layer 335 is formed around the via 304. A backside contact 342 is formed through a portion of the backside dielectric layer 335. Like the frontside contact 332, the backside contact 342 includes conductive materials the same as or similar to the materials of the first and second conductive layers 324-1 and 324-2. A BSPDN (not shown) (also referred to herein as backside interconnects) is formed on the backside dielectric layer 335 to connect to the backside contact 342. The BSPDN includes various BSPDN structures such as, but not necessarily limited to, interconnects in a power supply path from voltage regulator modules (VRMs) to circuits. The interconnects can include, for example, power and ground planes in circuit boards, cables, connectors and capacitors associated with a power supply. Backside power delivery prevents BEOL routing congestion, resulting in power performance benefits. The BSPDN delivers a source voltage to the portions of the doped semiconductor layer 315 on the left side of the nanosheet transistor in FIG. 3E and forming the source of the nanosheet transistor. The source voltage is delivered through the backside contact 342, the via 304 and the first conductive layer 324-1. The frontside interconnect portion 330 provides a drain voltage to the portions of the doped semiconductor layer 315 on the right side of the nanosheet transistor in FIG. 3E and forming the drain of the nanosheet transistor. The drain voltage is delivered through the frontside contact 332 and the second conductive layer 324-2.

Like the semiconductor structures 100 and 200, in the semiconductor structure 300, the nanosheet transistor in the upper device layer is staggered with respect to a nanosheet transistor disposed in the lower device layer. At least a portion of the via 304 is disposed in the backside dielectric layer 335 on a side of the nanosheet transistor disposed in the lower device layer.

As can be understood, the portions of the doped semiconductor layers 315 forming the source and drain of the nanosheet transistor (e.g., doped semiconductor sidewall portions) each include a first continuous layer disposed on a first side of the corresponding first or second conductive layer 324-1 or 324-2 and a second continuous layer disposed on a second side of the corresponding first or second conductive layer 324-1 or 324-2.

FIG. 4 depicts a cross-sectional view of the semiconductor structure of FIG. 3E including a cross-section line A-A′. FIGS. 5 and 6 depict cross-sectional views of the semiconductor structure of FIG. 4 taken along the line A-A′, according to a first and second alternative embodiments. In more detail in the first alternative embodiment (ALT. 1) of the semiconductor structure 300 shown in FIG. 5, the first conductive layer 324-1 overlaps an entirety of at least one side of one or more sidewall portions of the doped semiconductor layer 315 on the left side of the nanosheet transistor in FIGS. 3E and 4. In other words, as shown in FIG. 5, an area of the first conductive layer 324-1 (e.g., length*width) is the same as an area (e.g., length*width) of a sidewall portion of the doped semiconductor layer 315 on which the first conductive layer 324-1 is disposed. The length and width in this case represent dimensions in the vertical and horizontal directions in FIG. 5. In the second alternative embodiment (ALT. 2) of the semiconductor structure 300 shown in FIG. 6, the first conductive layer 324-1 overlaps part of at least one side of one or more sidewall portions of the doped semiconductor layer 315 on the left side of the nanosheet transistor in FIGS. 3E and 4. In other words, as shown in FIG. 6, an area of the first conductive layer 324-1 (e.g., length*width) is less than an area (e.g., length*width) of a sidewall portion of the doped semiconductor layer 315 on which the first conductive layer 324-1 is disposed. In FIG. 6, the length of the first conductive layer 324-1 is the same as the length of the sidewall portion of the doped semiconductor layer 315, but the width of the first conductive layer 324-1 is less than the width of the sidewall portion of the doped semiconductor layer 315.

FIGS. 5 and 6 further illustrate a source/drain region 314 of a transistor in the lower device level of the semiconductor structure 300. As can be seen, the source/drain region 314 is staggered with respect to the doped semiconductor layer 315 functioning as the source for the transistor in the upper device level. FIGS. 5 and 6 provide further details of the configuration of backside contact 342, and further depict additional backside contact 343 formed in the backside dielectric layer 335, which is connected to source/drain region 314 through first and second backside vias 344 and 345, which are also formed in the backside dielectric layer 335.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide structures for and techniques for forming terminal region contact structures for FETs. The illustrative embodiments advantageously include a via (e.g., via 104, 204 or 304) manufactured as non-sacrificial placeholder during formation of a lower device level, and a metal contact (e.g., conductive layer 124-1, 224-1 or 324-1) formed through part of a terminal region of a FET in an upper device layer. The metal contact is formed on and contacts the via so that backside power can be provided to the terminal region of the FET through the metal contact and the via.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a transistor comprising a terminal region, wherein the terminal region comprises doped semiconductor sidewall portions;
a conductive layer disposed through the terminal region, wherein the doped semiconductor sidewall portions are disposed on sides of the conductive layer; and
a via connected to the conductive layer.

2. The semiconductor device of claim 1, wherein the terminal region comprises a source region of the transistor.

3. The semiconductor device of claim 1, wherein:
the transistor comprises a nanosheet field-effect transistor including a stacked structure of a plurality of gate structures alternately stacked with a plurality of channel regions; and
the terminal region is disposed on a side of the stacked structure.

4. The semiconductor device of claim 3, wherein the doped semiconductor sidewall portions comprise a plurality of different crystal grains.

5. The semiconductor device of claim 4, wherein grain boundaries of at least a portion of the plurality of different crystal grains are disposed between at least two adjacent channel regions of the plurality of channel regions.

6. The semiconductor device of claim 1, wherein the via is connected between the conductive layer and one of a voltage source, a signal output portion and a signal input portion at a backside of the semiconductor device.

7. The semiconductor device of claim 1, wherein the transistor is staggered with respect to an additional transistor disposed under the transistor.

8. The semiconductor device of claim 7, wherein at least a portion of the via is disposed on a side of the additional transistor.

9. The semiconductor device of claim 1, wherein the doped semiconductor sidewall portions comprise a plurality of first sidewall portions disposed on a first side of the conductive layer and a plurality of second sidewall portions disposed on a second side of the conductive layer.

10. The semiconductor device of claim 9, wherein the plurality of first sidewall portions and the plurality of second sidewall portions comprise respective pyramid-shaped portions.

11. The semiconductor device of claim 9, wherein adjacent ones of the plurality of first sidewall portions contact each other and adjacent ones of the plurality of second sidewall portions contact each other.

12. The semiconductor device of claim 1, wherein the doped semiconductor sidewall portions comprise a first continuous layer disposed on a first side of the conductive layer and a second continuous layer disposed on a second side of the conductive layer.

13. The semiconductor device of claim 12, wherein the conductive layer overlaps an entirety of at least one side of at least one of the first continuous layer and the second continuous layer.

14. The semiconductor device of claim 1, wherein the via comprises a different material from a material of the conductive layer.

15. A semiconductor device comprising:
a transistor comprising a conductive layer disposed through at least a source region;
wherein the source region comprises doped semiconductor portions disposed on sides of the conductive layer; and
a via connected to the conductive layer and disposed in a dielectric layer under the transistor.

16. The semiconductor device of claim 15, wherein the doped semiconductor portions comprise a plurality of first portions disposed on a first side of the conductive layer and a plurality of second portions disposed on a second side of the conductive layer.

17. The semiconductor device of claim 15, wherein the doped semiconductor portions comprise a first continuous layer disposed on a first side of the conductive layer and a second continuous layer disposed on a second side of the conductive layer.

18. A semiconductor device comprising:
a first device level comprising a first nanosheet transistor;
a second device level stacked on the first device level and comprising a second nanosheet transistor; and
a conductive layer disposed in at least one of a source region and a drain region of the second nanosheet transistor;
wherein doped semiconductor portions contact sides of the conductive layer in the at least one of the source region and the drain region.

19. The semiconductor device of claim 18, wherein the doped semiconductor portions comprise a plurality of first portions disposed on a first side of the conductive layer and a plurality of second portions disposed on a second side of the conductive layer.

20. The semiconductor device of claim 18, wherein the doped semiconductor portions comprise a first continuous layer disposed on a first side of the conductive layer and a second continuous layer disposed on a second side of the conductive layer.
